(19) United States
(12) Patent Application Publication
(10) Pub. No.: US 2014/0217355 A1
(43) Pub. Date: Aug. 7, 2014

(54) SEMICONDUCTOR LIGHT EMITTING DEVICE

(71) Applicants: RENSSELAER POLYTECHNIC INSTITUTE, Troy, NY (US); SAMSUNG ELECTRONICS CO., LTD., Gyeonggi-do (KR)

(72) Inventors: Gi Bum KIM, Hwaseong (KR); Ming MA, New York City, NY (US); Ahmed NOEMAUN, Troy, NY (US); E. Fred SCHUBERT, Troy, NY (US); Jae-Hee CHO, Troy, NY (US); Cheol Soo SONE, Seoul (KR); Sung Tae KIM, Seoul (KR); Chan Mook LIM, Seongnam (KR)

(73) Assignees: RENSSELAER POLYTECHNIC INSTITUTE; SAMSUNG ELECTRONICS CO., LTD., Gyeonggi-do (KR)

(21) Appl. No.: 13/759,585

(22) Filed: Feb. 5, 2013

(51) Int. Cl. H01L 33/22

(52) U.S. Cl. CPC H01L 33/22
USPC 257/13

(57) ABSTRACT

A semiconductor light emitting device includes: a semiconductor laminate having first and second conductivity type semiconductor layers and an active layer formed between the first and second conductivity type semiconductor layers; first and second electrodes connected to the first and second conductivity type semiconductor layers, respectively; and a micro-pattern formed on a light emitting surface from which light generated from the active layer is output, wherein a section of the micro-pattern parallel to the light emitting surface has a polygonal shape.

### BACKGROUND OF THE INVENTION

1. Field of the Invention

The present invention relates to a semiconductor light emitting device.

2. Description of the Related Art

In general, a semiconductor light emitting diode (LED) has been widely used as a light source in a full-color display device, an image scanner, various signaling systems, or an optical communications device. In an LED, light is generated in an active layer using a principle of the recombination of electrons and holes and emitted. In particular, a nitride semiconductor has come to prominence as a material of a light emitting device able to cover a broad wavelength range, including blue and green light bands, according to a composition ratio thereof.

Luminance efficiency of a semiconductor light emitting device is determined by internal quantum efficiency and light extraction efficiency (or external quantum efficiency). In particular, light extraction efficiency is greatly affected by optical factors, e.g., a refractive index of each structure and/or a flatness of an interface, or the like, of a light emitting device.

However, in terms of light extraction efficiency, a semiconductor light emitting device has radical limitations.

A semiconductor layer constituting a semiconductor light emitting device has a high refractive index relative to ambient air, an encapsulated material, or a substrate, a critical angle for determining an incident angle range for emitting light is reduced and, as a result, a considerable amount of light generated in an active layer is totally internally reflected so as to propagate in an undesired direction or be lost during a total internal reflection process, lowering light extraction efficiency.

The low light extraction efficiency limits enhancement of luminous efficiency of a semiconductor light emitting device.

### SUMMARY OF THE INVENTION

Thus, in the art, a semiconductor light emitting device having a structurally improved light emitting surface in an optical aspect such that light extraction efficiency thereof is not degraded during a light extraction process is required.

According to an aspect of the present invention, there is provided a semiconductor light emitting device including: a semiconductor laminate having first and second conductivity type semiconductor layers and an active layer formed between the first and second conductivity type semiconductor layers; first and second electrodes connected to the first and second conductivity type semiconductor layers, respectively; and a micro-pattern formed on a light emitting surface from which light generated from the active layer is output, wherein a section of the micro-pattern parallel to the light emitting surface has a polygonal shape.

An internal angle of the micro-pattern having a polygonal shape toward the center of the section thereof may be equal to or less than 90°.

The polygonal shape of the micro-pattern may have three or more internal angles equal to or less than 60°.

The polygonal shape of the micro-pattern may have a plurality of tip portions, and internal angles of the plurality of tip portions toward the center of the section may be less than 60°.

For example, the polygonal shape of the micro-pattern may be a triangular or quadrangular. Also, the micro-pattern may have a pillar structure or a trigonal pyramidal structure.

The micro-pattern may be formed as a graded refractive index layer having a refractive index distribution decreased away from the light emitting surface.

The micro-pattern may include a first material layer formed on the second conductivity type semiconductor layer and having a first refractive index and a second material layer formed on the first material layer and having a second refractive index lower than that of the first refractive index.

The first refractive index may be equal to or smaller than that of the second conductivity type semiconductor layer.

The micro-pattern may further include a third material layer formed between the first and second material layers and having a refractive index between the first and second refractive indices.

The third material layer may be a plurality of material layers formed to be (composition of first material layer)₁₋ₓ(composition of second material layer)ₓ ((0<x<1)), respectively, wherein x value may be increased in a direction from the first material layer toward the second material layer.

### BRIEF DESCRIPTION OF THE DRAWINGS

The above and other aspects, features and other advantages of the present invention will be more clearly understood from the following detailed description taken in conjunction with the accompanying drawings, in which:

FIG. 1 is a schematic perspective view of a semiconductor light emitting device according to an embodiment of the present invention;

FIG. 2 is an enlarged perspective view of a micro-pattern of portion ‘A’ in FIG. 1;

FIG. 3 is a top plan view of the micro-pattern illustrated in FIG. 2;

FIG. 4 is a perspective view illustrating another example of a micro-pattern that may be employed in an embodiment of the present invention;

FIGS. 5A to 5C are perspective views illustrating various examples of fine-patterns (pillar type) that may be employed in an embodiment of the present invention;

FIGS. 6A to 6C are perspective views illustrating various examples of fine-patterns (pyramid type) that may be employed in an embodiment of the present invention;

FIG. 7 is a graph showing light extraction efficiency improvement effects of various embodiments of the present invention;

FIG. 8 is a plan view of a semiconductor light emitting device according to another embodiment of the present invention;

FIG. 9 is a partially cut-away cross-sectional view of the semiconductor light emitting device illustrated in FIG. 8;

FIGS. 10A and 10B are partially cut-away cross-sectional views of the semiconductor light emitting device illustrated in FIG. 8;

FIG. 11 is a schematic perspective view of a semiconductor light emitting device according to another embodiment of the present invention; and

FIG. 12 is a cross-sectional view of the semiconductor light emitting device illustrated in FIG. 11.

### DETAILED DESCRIPTION OF THE PREFERRED EMBODIMENT

Embodiments of the present invention will now be described in detail with reference to the accompanying drawings. The invention may, however, be embodied in many different forms and should not be construed as being limited to the embodiments set forth herein. Rather, these embodiments are provided so that this disclosure will be thorough and complete, and will fully convey the scope of the invention to those skilled in the art. In the drawings, the shapes and dimensions of elements may be exaggerated for clarity, and the same reference numerals will be used throughout to designate the same or like components.

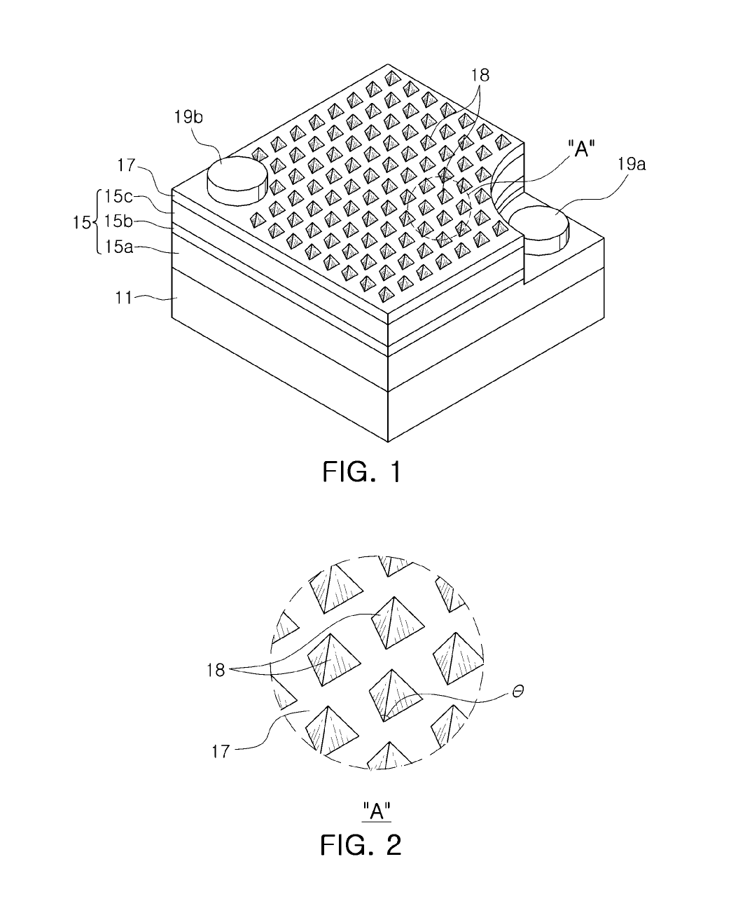

FIG. 1 is a schematic perspective view of a semiconductor light emitting device according to an embodiment of the present invention.

As illustrated in FIG. 1, a semiconductor light emitting device 10 according to the present embodiment includes a semiconductor laminate 15 formed on a substrate 11. The semiconductor laminate 15 includes first and second conductivity type semiconductor layers 15a and 15c and an active layer 15b formed therebetween.

The first conductivity type semiconductor layer 15a may be a group III-V nitride semiconductor layer, for example, an n-GaN layer. The second conductivity type semiconductor layer 15c may be a group III-V nitride semiconductor layer, for example, a p-GaN layer or a p-GaN/AlGaN layer.

The active layer 15b may be a group III-V nitride semiconductor layer of a GaN group of InₓAl_{y}Ga_{1-x-y}N (0≦x<1, 0≦y<1, and 0≦x+y<1), and may be a multi-quantum well (MQW) or a single quantum well. For example, the active layer 15b may have a GaN/InGaN/GaN MQW or GaN/AlGaN/GaN MQW structure.

First and second electrodes 19a and 19b are formed to be connected to the first and second conductivity type semiconductor layers 15a and 15c, respectively. The first electrode 19a and the second electrode 19b may include a contact electrode material that may be a metal such as nickel (Ni), aluminum (Al), silver (Ag), gold (Au) or a transparent conductive material, and may have a multilayered structure including two or more layers. In order to be connected to an external circuit, the first electrode 19a and the second electrode 19b may further include an electrode bonding material such as gold (Au). In this case, a barrier metal layer such as titanium (Ti) may be further provided between the contact electrode and the bonding electrode, as necessary.

In the present embodiment, a transparent electrode layer 17 may be formed on the second conductivity type semiconductor layer 15c. The transparent electrode layer 17 may be formed of a transparent conductive oxide. For example, a material used to form the transparent electrode may be any one selected from the group consisting of indium tin oxide (ITO), zinc-doped indium tin oxide (ZITO), zinc indium oxide (ZIO), gallium indium oxide (GIO), zinc tin oxide (ZTO), fluorine-doped tin oxide (FTC)), aluminum-doped zinc oxide (AZO), gallium-doped zinc oxide (GZO), In₄Sn₂O₁₂ and Zn₍₁₋ₓ₎MgₓO (zinc magnesium oxide, 0≦x≦1). Specifically, the material may include Zn₂In₂O₅, GaInO₃, ZnSnO₃, F-doped SnO₂, Al-doped ZnO, Ga-doped ZnO, MgO, ZnO, and the like.

In the semiconductor light emitting device, when a predetermined voltage is applied between the first electrode 19a and the second electrode 19b, electrons and holes are injected from the first conductivity type semiconductor layer 15a and the second conductivity type semiconductor layer 15c to the active layer 15b and recombined in the active layer 15b to generate light therefrom.

A light emitting surface of the semiconductor light emitting device 10 includes a micro-pattern 18. Here, the light emitting surface refers to a particular surface of the light emitting device 10 from which light generated in the active layer 15b is output.

In the present embodiment, the light emitting surface is illustrated as a surface on the second conductivity type semiconductor layer 15c, strictly speaking, a surface of the transparent electrode layer 17, but it may be a surface in relation to a different semiconductor layer or one surface of the substrate according to a structure of the semiconductor light emitting device.

In the present embodiment, as illustrated in FIG. 2, the micro-pattern 18 has a triangular pyramidal shape, and a triangular section of the triangular pyramid is parallel to the light emitting surface.

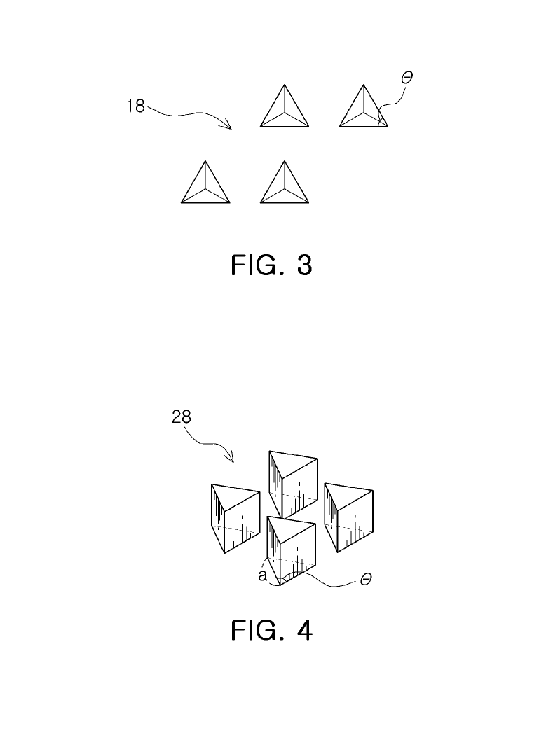

As illustrated in FIG. 3, when viewed from above, the micro-pattern has three angled portions. The provision of the angled portions formed on lateral portions of the micro-pattern 18 may greatly contribute to the effective extraction of light. Namely, such angled portions may advantageously act to enhance light extraction efficiency relative to a pattern having a gentle lateral surface, e.g., a hemispherical pattern. Thus, by applying the angled portions to the lateral surfaces of the micro-pattern, a light extraction effect can be increased

Preferably, the angled portions employed in the micro-pattern may have a right angle or an acute angle (i.e., an angle at which an internal angle toward the center of the section is equal to or less than 90°) in terms of light extraction efficiency.

The micro-pattern 18 illustrated in FIGS. 2 and 3 is illustrated as having a triangular pyramidal shape having an equilateral triangular section (or bottom surface) in which internal angles are 60°, respectively, but the present invention is not limited thereto. For example, the micro-pattern 18 may have a pillar structure having the same shape.

FIG. 4 illustrates a micro-pattern 28 having a pillar structure, rather than having a projection structure (i.e., a pointed tip structure), although it has an equilateral triangular section similar to the sectional shape illustrated in FIG. 3. The micro-pattern 28 illustrated in FIG. 4 may also have angled portions on lateral portions to reinforce the light extraction function.

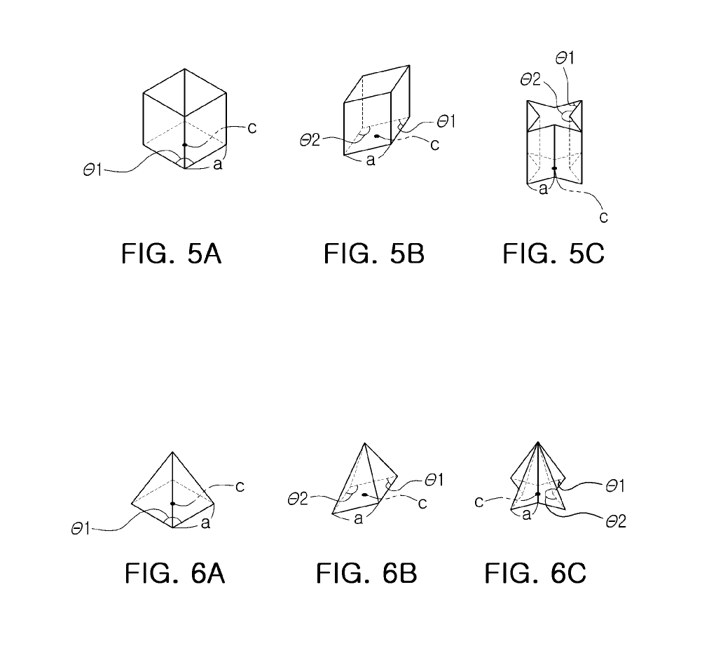

In another example, a section of a micro-pattern may have various polygonal shapes. FIGS. 5A to 5C and FIGS. 6A to 6C illustrate some examples thereof.

First, referring to FIGS. 5A to 5C, it is illustrated that a quadrangular pillar (FIG. 5A) has a substantially square cross-section, a quadrangular pillar (FIG. 5B) has a parallelogram as a cross-sectional shape, and a pillar (FIG. 5C) has a cross-section similar to that of a dagger.

The section of the micro-pattern illustrated in FIG. 5C has four sharply angled portions. Namely, the micro-pattern may have a shape having a plurality of tip portions in which the internal angles θ1 toward the center of the section are less than 60°. In the present embodiment, the provision of a plurality of tip portions having sharp internal angles less than 60° may drastically increase light extraction efficiency due to the angled portions on the lateral portions of the fine pattern. As the sectional shape, various shapes similar to a star-like shape, and the like, may be considered.

Referring to FIGS. 6A to 6C, micro-patterns each of which having a structure having a pyramidal shape different from the shapes of the foregoing examples, while having the sections corresponding to the sectional shapes illustrated in FIGS. 5A to 5C, are illustrated. As illustrated in FIGS. 6A to 6C, the micro-patterns may be implemented to have various pyramid structures such as a quadrangular pyramid (FIG. 6A) having a substantially square cross-section, a quadrangular pyramid (FIG. 6B) having a parallelogram as a cross-sectional shape, and a pyramid (FIG. 6C) having a cross-section similar to that of a dragger.

The improvement effect of light extraction efficiency by employing the angled portions on the lateral portions of the micro-pattern as described above was confirmed through an experiment conduced under the following conditions by using various patterns.

### Embodiment 1

Three nitride semiconductor light emitting devices were fabricated as follows. Namely, an n-type GaN layer, an active layer having an InGaN/GaN multi-quantum well (MQW) structure, and a p-type AlGaN/GaN layer were grown on a sapphire substrate, and an ITO layer having a thickness of approximately 150 nm was formed on a surface of the p-type GaN layer, as a transparent electrode layer.

Subsequently, portions of the n-type GaN layer were exposed by applying mesa etching, and an n-side electrode and a A-side electrode were subsequently formed on exposed n-type GaN layer regions and ITO layer regions, respectively.

A layer for a micro-pattern was formed on the ITO layer to have a uniform thickness of 0.7 μm, and a square pillar micro-pattern having a square section was fabricated (Please see FIG. 5(a)).

Also, micro-patterns implemented in three nitride semiconductor light emitting devices were formed to have different sizes. Namely, micro-patterns were formed such that lengths (a) of one side of the square section were differentiated to be 4 μm, 6 μm, and 8 μm, respectively. Here, a charge rate of the patterns (i.e., an occupancy area rate of the patterns) was designed to be 19.6%.

### Embodiment 2

Nitride semiconductor light emitting devices were fabricated under the same conditions as those of Embodiment 1, and micro-patterns were fabricated to have a trigonal prism cross-section (Please see FIG. 4). Also, the micro-patterns were formed such that lengths (a) of one side of the equilateral triangle were differentiated to be 4 μm, 6 μm, and 8 μm and a charge rate (19.6%) of the patterns was uniformly maintained.

### Embodiment 3

Nitride semiconductor light emitting devices were fabricated under the same conditions as those of Embodiment 1, and micro-patterns were fabricated to have a pillar shape having four tip portions in cross-section (Please see FIG. 5). Also, the micro-patterns were formed such that lengths (a) of one sides of the tip portions were differentiated to be 4 μm, 6 μm, and 8 μm and a charge rate (19.6%) of the patterns was uniformly maintained.

### Comparative Example

Nitride semiconductor light emitting devices were fabricated under the same conditions as those of Embodiment 1, and micro-patterns were fabricated to have a cylindrical shape without any angled portions on a lateral portion thereof. Also, the micro-patterns were formed such that diameters of the circle as a cross-section were differentiated to be 4 μm, 6 μm, and 8 μm and a charge rate (19.6%) of the patterns was uniformly maintained.

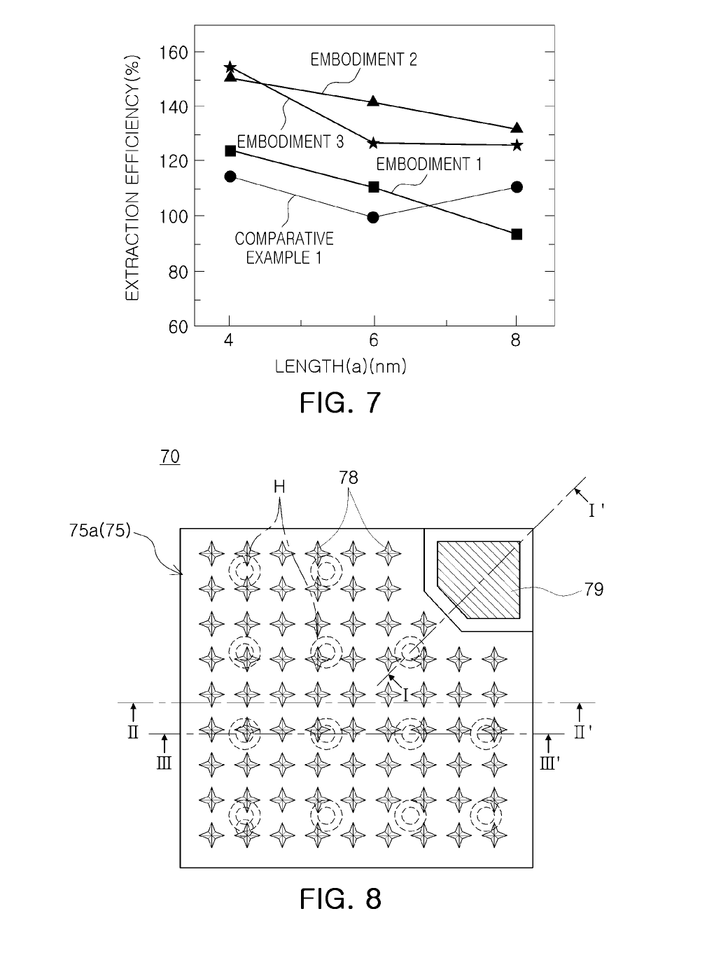

Based on light output, as a reference (100%), of the semiconductor light emitting device of Comparative example in which the micro-pattern (cylindrical shape) has a diameter of 6 μm, light outputs of Embodiments 1 to 3 and Comparative example are shown in the graph of FIG. 7.

Referring to FIG. 7, it can be seen that Embodiments 1 to 3 having angled portions on the lateral portions has significantly improved light extraction efficiency relative to Comparative example in which the micro-pattern has a substantially cylindrical shape. In detail, although there are slight differences in terms of the enhancement of light extraction efficiency depending on the sizes of micro-patterns, it can be seen that light extraction efficiency was drastically improved in the case of the micro-pattern having the trigonal prism (Embodiment 2) and the micro-pattern having a pillar structure having a plurality of tip portions (Embodiment 3).

In this manner, it is confirmed that, in the case of employing the angled portion in the lateral portion of the micro-pattern, as the internal angle of the angled portion is reduced, light extraction efficiency is further improved. Namely, as shown in the results of Embodiments 2 and 3, it can be understood that light extraction efficiency was drastically improved in the structure in which internal angles less than 60° had three or more shapes.

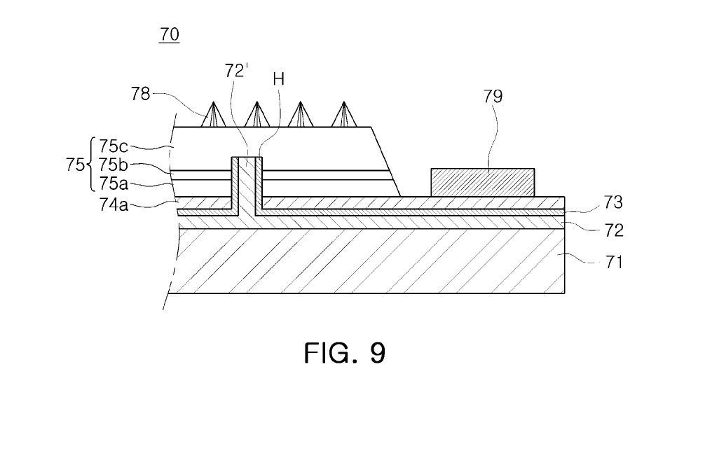

FIG. 8 is a plan view of a semiconductor light emitting device according to another embodiment of the present invention. FIG. 9 is a lateral-sectional view taken along line I-I′ of the semiconductor light emitting device illustrated in FIG. 8.

Referring to FIGS. 8 and 9, a semiconductor light emitting device 70 according to the present embodiment includes a semiconductor laminate 75 including first and second conductivity type semiconductor layers 75a and 75c and an active layer 75b positioned therebetween. The semiconductor laminate 75 has first and second main surfaces provided by the first and second conductivity type semiconductor layers 75a and 75c and positioned in the mutually opposite sides.

The semiconductor laminate 75 may be a group III-VI compound semiconductor such as a nitride semiconductor, but the present invention is not limited thereto. In the present embodiment, after a separate growth substrate is grown in order of the first conductivity type semiconductor layer 75a, the active layer 75b, and the second conductivity type semiconductor layer 75c of the semiconductor laminate 75, a wiring structure is formed on a first plane, and a support substrate 71 is employed.

Here, the support substrate 71 employed in the present embodiment may be a substrate having electrical conductivity. The support substrate 71 may be easily provided through a plating process. Subsequently, the growth substrate is removed from the semiconductor laminate 75 to obtain the device structure illustrated in FIG. 8. In a normal case, the first and second conductivity type semiconductor layers 75a and 75c may be n-type and p-type semiconductor layers, respectively.

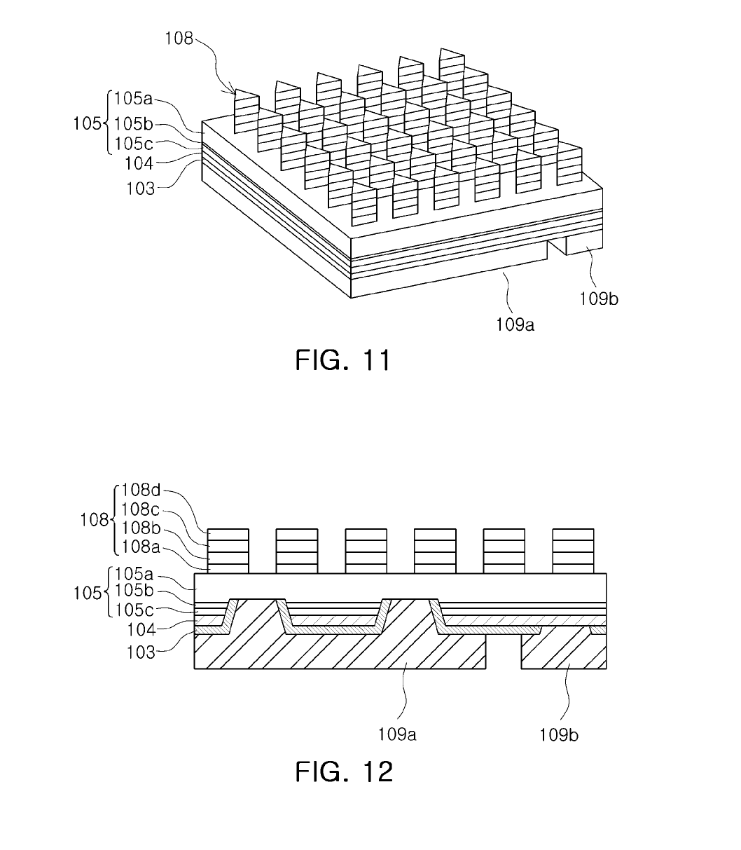

In the present embodiment, the configuration employing the support substrate is illustrated, but electrode structures may be formed without a support substrate (Please see FIGS. 11 and 12).

In the present embodiment, a second electrode 74 may be formed on a second main surface of the semiconductor laminate 75 so as to be connected to the second conductivity type semiconductor layer 75c. The second electrode 74 may be a highly reflective ohmic-contact layer reflecting light generated from the active layer 75b. For example, the highly reflective ohmic-contact layer may be made of a material selected from the group consisting of silver (Ag), nickel (Ni), aluminum (Al), rhodium (Rh), palladium (Pd), iridium (Ir), ruthenium (Ru), magnesium (Mg), zinc (Zn), platinum (Pt), gold (Au), and any combination thereof.

A first electrode 72 connected to the first conductivity type semiconductor layer 75a is provided on the second main surface of the semiconductor laminate 75. As in the present embodiment, connection of the first electrode 72 and the first conductivity type semiconductor layer may be accomplished by using a contact hole H.

As illustrated in FIG. 9, at least one contact hole H may be formed in the semiconductor laminate 75 such that it extends by passing through the second conductivity type semiconductor layer 75c and the active layer 75b until a portion of the first conductivity type semiconductor layer 75a is exposed. The first conductivity type semiconductor layer 75a may be exposed through the second main surface by the contact hole H formed thusly.

The first electrode 72 may be connected to the exposed region of the first conductivity type semiconductor layer 75a provided by the contact hole H, through an electrode region 72′ extending from the first electrode 72. Accordingly, the first electrode 72 positioned on the second main surface may be electrically connected to the first conductivity type semiconductor layer 75a.

The contact hole H may be formed before a wiring structure is formed after the semiconductor laminate 75 is formed on a growth substrate. In the present embodiment, the contact hole H is illustrated as having the form of a via, but it may be variously implemented as long as a portion of the first conductivity type semiconductor layer 75a can be exposed thereby.

In the present embodiment, as illustrated in FIG. 8, a plurality of contact holes H may be formed to be positioned over the entire effective light emitting area. Since the plurality of contact holes H are formed over the large area, a current may be uniformly distributed and the structure may be advantageously used in a semiconductor light emitting device having a large area for a high output.

An insulating separation layer 73 may be formed to easily electrically separate the first electrode 72 and the second electrode 74 provided on the main surface of the semiconductor laminate 75. The insulating separation layer 73 may be formed to extend between an inner side wall of the contact hole H and the electrode region 72′ of the first electrode 72.

In the present embodiment, the support substrate 71 may be provided with the first and second electrodes 72 and 74 on the second main surface of the semiconductor laminate 75, with a wiring structure comprised of the insulating separation layer 73 interposed therebetween.

The support substrate 71 employed in the present embodiment is a substrate having electrical conductivity. As illustrated in FIG. 9, the support substrate 71 is electrically separated from the second electrode 74 by the insulating separation layer 73, and electrically connected to the first electrode 72, and thus, the support substrate 71 may be provided as an electrode structure, for the first conductivity type semiconductor layer 75a, together with the first electrode 72. Namely, the conductive support substrate 71 may be connected together with an external circuit positioned on a mounting surface of the semiconductor light emitting device 70.

In the present embodiment, a bonding region of one electrode of the semiconductor light emitting device 70 formed on an electrode pad 79 connected to the second electrode 74 may be provided on the first main surface opposite the second main surface. The semiconductor light emitting device 70 may further include a passivation layer (not shown) made of an insulating material formed at least on a lateral surface of the semiconductor laminate 75.

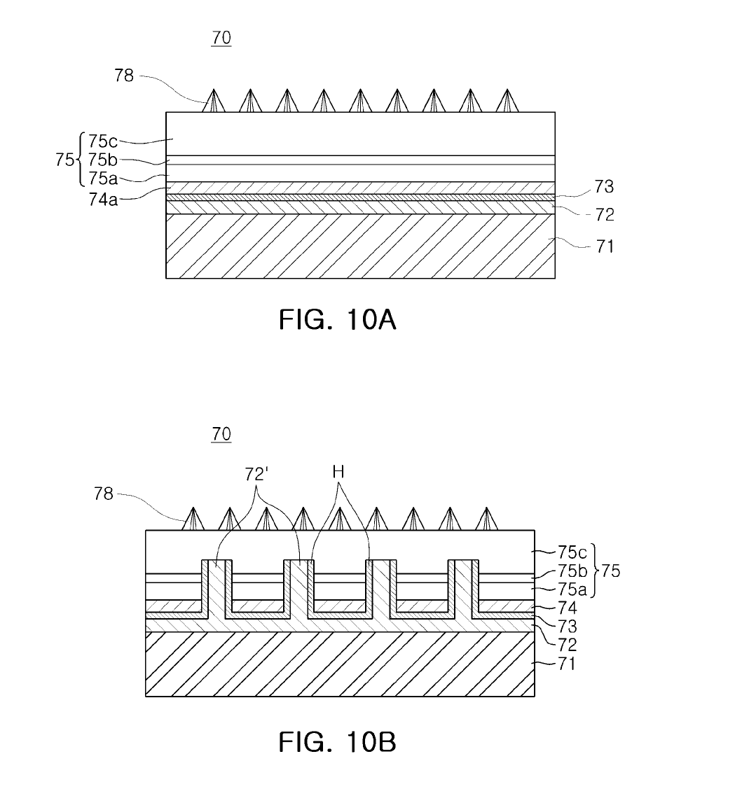

FIG. 10A is a cross-sectional view taken along line II-II′ of the semiconductor light emitting device 70 illustrated in FIG. 8 and FIG. 10B is a cross-sectional view taken along line III-III′.

Referring to FIG. 10A, the semiconductor light emitting device 70 is configured by sequentially stacking the first electrode 72, the insulating separation layer 73, the second electrode 74, and the semiconductor laminate 75 on the support substrate 71 having electrical conductivity.

Meanwhile, referring to FIG. 10B, the semiconductor light emitting device 70 has a structure in which the first electrode 72, the insulating separation layer 73, the second electrode 74, and the semiconductor laminate 75 are sequentially stacked on the support substrate 71, similar to the stacked structure illustrated in FIG. 10A, except for regions in which holes are formed. Namely, the semiconductor light emitting device 70 has the structure in which the plurality of contact holes H connecting the first electrode 72 to the first 75a are arranged at regular intervals. The plurality of contact holes H may reinforce uniform current distribution in the semiconductor light emitting device 70.

In the present embodiment, a micro-pattern 78 may be formed on the first conductivity type semiconductor layer 75a as a main light emitting surface of the semiconductor light emitting device 70. The micro-pattern 78 has a section having four tip portions and has a pyramid structure.

Namely, the micro-pattern 78 employed on the present embodiment has a section having four sharp angled portions and an internal angle θ1 of each of the angled portions toward the center of the micro-pattern 78 is less than 60°. Thus, since the tip portion having a sharp internal angle θ1 of less than 60° is formed on the lateral portion of the micro-pattern 78, light extraction efficiency can be drastically increased.

FIG. 11 is a schematic perspective view of a semiconductor light emitting device according to another embodiment of the present invention, and FIG. 12 is a cross-sectional view of the semiconductor light emitting device illustrated in FIG. 11.

Referring to FIGS. 11 and 12, a semiconductor light emitting device 100 includes a semiconductor laminate 105 comprised of first and second conductivity type semiconductor layers 105a and 105c and an active layer 105b positioned therebetween.

The semiconductor laminate 105 has first and second main surfaces provided by the first and second conductivity type semiconductor layers 105a and 105c and positioned in the opposite sides. The semiconductor laminate 105 may be a group III-VI compound semiconductor such as a nitride semiconductor, but the present invention is not limited thereto.

In the present embodiment, unlike the embodiment illustrated in FIG. 11, a support substrate may not be employed and only an electrode structure may be formed.

A first electrode 109a connected to the first conductivity type semiconductor layer 105a is provided on the second main surface of the semiconductor laminate 105. Like the foregoing embodiment, the first electrode 109a and the first conductivity type semiconductor layer 105a may be connected by using a contact hole.

As illustrated in FIG. 12, at least one contact hole may be formed in the semiconductor laminate 105 such that it extends by passing through the second conductivity type semiconductor layer 105c and the active layer 105b until a portion of the first conductivity type semiconductor layer 105a is exposed. The first conductivity type semiconductor layer 105a may be exposed through the second main surface by the contact hole formed thusly.

An ohmic-contact layer 104 may be formed on the second main surface of the semiconductor laminate 105 such that it is connected to the second conductivity type semiconductor layer 105c. The ohmic-contact layer 104 is formed to reflect light generated from the active layer 105b, and may be made of a material selected from the group consisting of silver (Ag), nickel (Ni), aluminum (Al), rhodium (Rh), palladium (Pd), iridium (Ir), ruthenium (Ru), magnesium (Mg), zinc (Zn), platinum (Pt), gold (Au), and any combination thereof. A second electrode 109b may be formed to be connected to the ohmic-contact layer 104.

The first electrode 109a provided on the second main surface of the semiconductor laminate 105 is separated from the second electrode 109b, and in order to guarantee electrical insulation between the ohmic-contact layer 104 and the first electrode 109a, an insulating separation layer 103 may be formed between the ohmic-contact layer 104 and the first electrode 109a. The insulating separation layer 103 may be formed to extend between an inner side wall of the contact hole and the first electrode 109a.

In the present embodiment, a micro-pattern 108 may be formed on the first conductivity type semiconductor layer 105a as a main light emitting surface of the semiconductor light emitting device 100. The micro-pattern 108 has a pillar structure, and a section of the pillar structure is provided to be parallel to the light emitting surface and has a triangular shape.

As illustrated in FIG. 11, when viewed from above, the micro-pattern 108 has three angled portions. The provision of the angled portions formed on the lateral portions of the micro-pattern 108 may greatly contribute to effective extraction of light.

In addition, in order to further improve light extraction efficiency, the micro-pattern employed in the present embodiment may have a graded refractive index layer (GRIN) structure.

The GRIN structure has a refractive index distribution such that a refracted index is reduced as it moves away from the light emitting source, guaranteeing a smooth passage of light in a light emission direction. The GRIN structure may include at least two material layers having different refractive indices. In the present embodiment, the GRIN structure includes four material layers 108a to 108d.

In order to satisfy a refractive index condition of the micro-pattern 108 for light extraction, the respective material layers may be made of a material selected from the group consisting of TiO₂, SiC, GaN, GaP, SiNₓ, ZrO₂, ITO, AlN, Al₂O₃, MgO, SiO₂, CaF₂, and MgF₂ but the components thereof are not limited thereto. The respective material layers may be formed through a sputtering method or an evaporation method.

The GRIN structure may include a first material layer 108a having a first refractive index and a second material layer 108d having a second refractive index lower than the first refractive index, and may additionally include at least one third material layer 108b formed between the first and second material layers 108a and 108d and having a refractive index between the first and second refractive indices. In the present embodiment, two third material layers 108b and 108c are included. The two third material layers 108b and 108c may be formed to be (composition of first material layer)₁₋ₓ(composition of second material layer)ₓ ((0<x<1)), and a refractive index distribution may be gradually decreased between the first refractive index and the second refractive index from the first material layer 108a to the second material layer 108d.

For example, the two third material layers 108b and 108c may be formed to be (composition of first material layer)₁₋ₓ(composition of second material layer)ₓ ((0<x<1)), and the x value may be increased from the first material layer 108a to the second material layer 108d.

For example, the first and second material layers 108a and 108d may be TiO₂ and SiO₂, and the third material layers 108b and 108c may be (TiO₂)₁₋ₓ(SiO₂)ₓ (0<x<1).

As discussed above, the two third material layers 108b and 108c may be (TiO₂)₁₋ₓ(SiO₂)ₓ or (ITO)₁₋ₓ(SiO₂)ₓ in which the rate of the SiO2 material is gradually increased in a direction toward the second material layer 108d.

In the present embodiment, a plurality of third material layers 108b and 108c are illustrated, but a single third material layer may be employed, and in this case, it may be formed such that (a composition of first material layer)₁₋ₓ(a composition of second material layer)ₓ ((0<x<1)), thus implementing a middle refractive index.

The first refractive index of the first material layer 108a is equal to or smaller than a refractive index of the material of the light emitting surface. For example, in the present embodiment, the first refractive index of the first material layer 108a may be equal to or smaller than a refractive index of the first conductivity type semiconductor layer 105a. A height and width of the micro-pattern 108 may range from 0.1 μm to 5 μm, but the present invention is not limited thereto. The micro-pattern 108 employed in the present embodiment may be formed by primarily taking a light extraction operation through lateral surfaces thereof into consideration.

As set forth above, according to embodiments of the invention, in a process of extracting light generated from the active layer of the semiconductor light emitting device, a light confinement phenomenon due to a difference between refractive indices of the semiconductor light emitting device and the atmosphere or an encapsulated material is reduced and light extraction efficiency is increased, thus enhancing luminous efficiency.

While the present invention has been shown and described in connection with the embodiments, it will be apparent to those skilled in the art that modifications and variations can be made without departing from the spirit and scope of the invention as defined by the appended claims.

1. A semiconductor light emitting device comprising:
a semiconductor laminate having first and second conductivity type semiconductor layers and an active layer formed between the first and second conductivity type semiconductor layers;
first and second electrodes connected to the first and second conductivity type semiconductor layers, respectively; and
a micro-pattern being made of a light transmissive material and formed on a light emitting surface from which light generated from the active layer is output,
wherein a section of the micro-pattern parallel to the light emitting surface has a polygonal shape and the polygonal shape of the micro-pattern has three or more internal angles equal to or less than 60°.

2-4. (canceled)

5. The semiconductor light emitting device of claim 1, wherein the micro-pattern has a pillar structure or a trigonal pyramidal structure.

6. The semiconductor light emitting device of claim 1, wherein the micro-pattern is formed as a graded refractive index layer having a refractive index distribution decreased away from the light emitting surface.

7. The semiconductor light emitting device of claim 1, wherein the micro-pattern comprises:
a first material layer formed on the second conductivity type semiconductor layer and having a first refractive index; and
a second material layer formed on the first material layer and having a second refractive index lower than that of the first refractive index.

8. The semiconductor light emitting device of claim 7, wherein the first refractive index is equal to or smaller than that of the second conductivity type semiconductor layer.

9. The semiconductor light emitting device of claim 7, wherein the micro-pattern further comprises a third material layer formed between the first and second material layers and having a refractive index between the first and second refractive indices.

10. The semiconductor light emitting device of claim 9, wherein the third material layer is formed to be (composition of first material layer)₁₋ₓ(composition of second material layer)ₓ (0<x<1).

11. The semiconductor light emitting device of claim 10, wherein the third material layer is a plurality of material layers, and the x value is increased in a direction from the first material layer toward the second material layer.

12. The semiconductor light emitting device of claim 10, wherein the micro-pattern is formed on any one of the first and second conductivity type semiconductor layers.

13. The semiconductor light emitting device of claim 12, wherein the light-transmissive material is different from that of the first and second conductivity type semiconductor layers.

14. The semiconductor light emitting device of claim 1, wherein the semiconductor laminate is made of a nitride semiconductor.

15. A semiconductor light emitting device comprising:
a semiconductor laminate having first and second main surfaces which face each other and having first and second conductivity type semiconductor layers providing the first and second main surfaces and an active layer formed between the first and second conductivity type semiconductor layers;
at least one contact hole connected to a region of the first conductivity type semiconductor layer through the active layer;
a first electrode formed on the second main surface of the semiconductor laminate and connected to the first conductivity type semiconductor layer through the at least one contact hole;
a second electrode connected to the second conductivity type semiconductor layer of the semiconductor laminate; and
a micro-pattern being made of a light transmissive material and formed on a light emitting surface from which light generated in the active layer is output, wherein a section of the micro-pattern parallel to the light emitting surface having a polygonal shape and the polygonal shape of the micro-pattern has three or more internal angles equal to or less than 60°.
